(19) United States
(12) Patent Application Publication
(10) Pub. No.: US 2014/0025324 A1
(43) Pub. Date: Jan. 23, 2014

(54) OPEN CIRCUIT VOLTAGE CALCULATING SYSTEM AND METHOD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: DE-HUA DANG, Shenzhen (CN)

(21) Appl. No.: 13/929,812

(22) Filed: Jun. 28, 2013

(30) Foreign Application Priority Data
Jul. 19, 2012 (CN) 201210250247X

(51) Int. Cl. G01R 31/36

(52) U.S. Cl. CPC G01R 31/3624
USPC 702/63

(57) ABSTRACT

An electronic device being used to calculate an open circuit voltage of a battery built in the electronic device. The electronic device reads a charging voltage and a charging current, a discharging voltage and a discharging current. The electronic device calculates the open circuit voltage of the battery according to the charging voltage, the charging current and the resistance if the battery is charging. The electronic device calculates the open circuit voltage of the battery according to the discharging voltage, the discharging current and the resistance if the battery is discharging.

### BACKGROUND

1. Technical Field

The embodiments of the present disclosure relate to battery management technology, and particularly to an open circuit voltage calculating system and method for a battery of an electronic device.

2. Description of Related Art

An electronic device includes a battery. The electronic device displays a battery percentage which indicates available energy presently stored in the battery. Each battery percentage corresponds to an open circuit voltage of the battery. However, the battery itself includes a resistance, the resistance influences accuracy of the open circuit voltage of the battery. Therefore, there is room for improvement in the art.

### BRIEF DESCRIPTION OF THE DRAWINGS

FIG. 1 is a block diagram of one embodiment of an electronic device including an open circuit voltage calculating system.

FIG. 2 is a block diagram of one embodiment of the open circuit voltage calculating system included in the electronic device of FIG. 1.

FIG. 3 is a flowchart of one embodiment of an open circuit voltage calculating method.

FIG. 4 illustrates a table indicating a relation between a battery open circuit voltage and a battery percentage.

### DETAILED DESCRIPTION

The disclosure is illustrated by way of examples and not by way of limitation in the figures of the accompanying drawings in which like references indicate similar elements. It should be noted that references to “an” or “one” embodiment in this disclosure are not necessarily to the same embodiment, and such references mean “at least one.”

In general, the word “module”, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory electronic device-readable medium or other storage device. Some non-limiting examples of non-transitory electronic device-readable media include CDs, DVDs, BLU-RAY, flash memory, and hard disk drives.

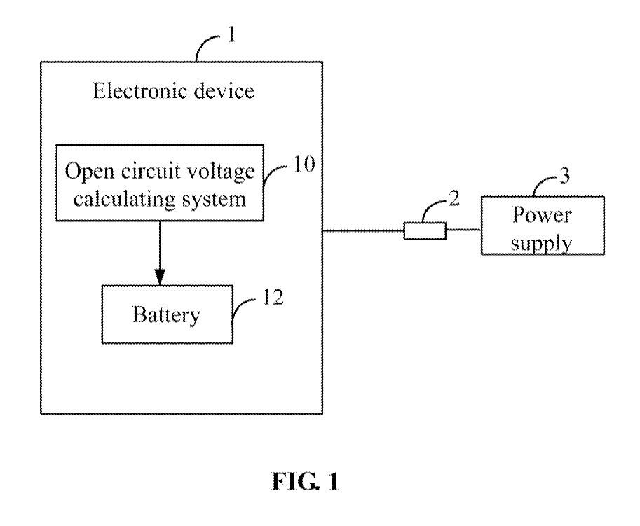

FIG. 1 is a block diagram of one embodiment of an electronic device 1. In this embodiment, the electronic device 1 includes an open circuit voltage calculating system 10 and a battery 12. The electronic device 1 is connected to a power supply 3 via a charger 2. The electronic device 1 may be, but is not limited to, a mobile phone, a tablet computer, a laptop computer or any other device which includes the battery 12.

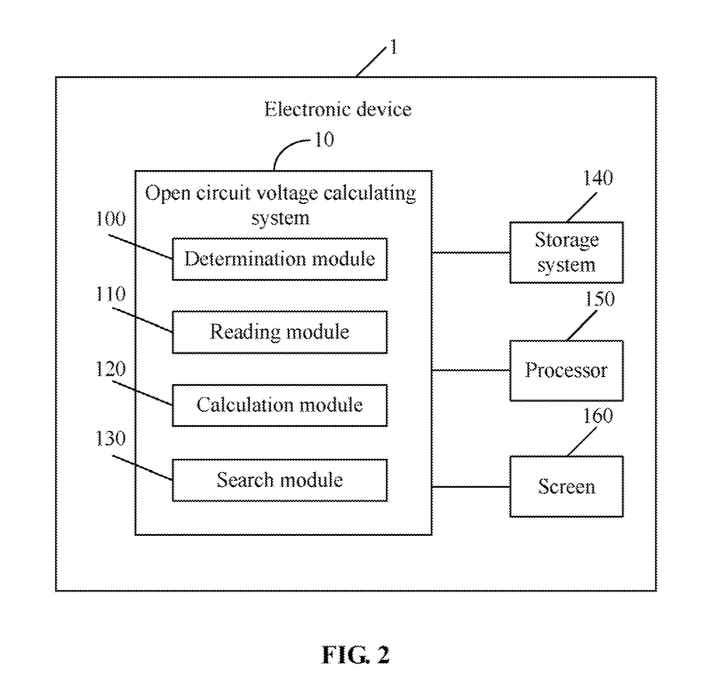

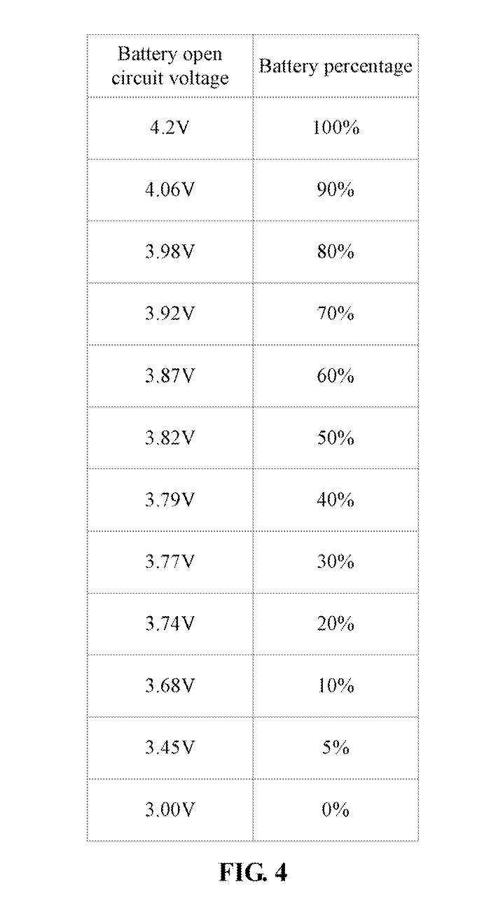

FIG. 2 is a block diagram of one embodiment of the open circuit voltage calculating system 12 included in the electronic device 1 of FIG. 1. The electronic device 1 includes a storage system 140, and at least one processor 150. In one embodiment, the open circuit voltage calculating system 10 includes a determination module 100, a reading module 110, a calculation module 120 and a search module 130. The modules 100-130 may include computerized code in the form of one or more programs that are stored in a storage system 140. The computerized code includes instructions that are executed by the at least one processor 150 to provide functions for the modules 100-130. The storage system 140 may be a memory, such as an EPROM memory chip, hard disk drive (HDD), or flash memory stick. Additionally, the electronic device 1 includes a screen 160. The screen 160 is used for showing a battery percentage. The storage system 140 also stores a table indicating a relation between a battery open circuit voltage and a battery percentage as shown in FIG. 4. Each battery open circuit voltage corresponds to one battery percentage. For example, the battery open circuit voltage 4.2V corresponds to the battery percentage 100% as shown in FIG. 4.

The determination module 100 determines if the battery 10 of the electronic device 1 is charging. In one embodiment, the determination module 110 determines that battery 10 of the electronic device 1 is charging upon the condition that the charger 2 is providing current to the battery 10. If the charger 2 is not providing current to the battery 10, the determination module 110 determines that the battery 10 of the electronic device 1 is discharging.

The reading module 110 reads a charging voltage and a charging current of the battery 10, in response to a determination that the battery 10 is charging. In one embodiment, when the battery 10 is charging, the battery 10 includes a charging current circuit. The charging voltage of the battery 10 is defined as a voltage between a positive pole and a negative pole of the battery 10 when the battery 10 is charging and the battery 10 includes the charging current circuit. The charging current of the battery 10 is defined as a current on the charging current circuit when the battery 10 is charging. The reading module 110 reads the charging voltage and the charging current of the battery 10 from the charging current circuit.

The reading module 110 also reads a discharging voltage and a discharging current of the battery 10, in response to the determination that the battery 10 is discharging. In one embodiment, when the battery 10 is discharging, the battery 10 includes a discharging current circuit. The discharging voltage of the battery 10 is defined as the voltage between the positive pole and the negative pole of the battery 10 when the battery 10 is discharging and the battery 10 includes the discharging current circuit. The discharging current of the battery 10 is defined as a current on the discharging current circuit when the battery 10 is discharging. The reading module 110 reads the discharging voltage and the discharging current of the battery 10 from the discharging current circuit.

The reading module 110 reads a resistance of the battery 10. The resistance is calculated by a formula, wherein the formula is as follows: R=(Va−Vb)/(Ia−Ib), where R represents the resistance, Va represents the charging voltage, Ia represents the charging current, Vb represents discharging voltage, and Ib represents the discharging current. Due to influence of temperature of the battery 10 or other factors (e.g., charging times of the battery 10), the resistance may vary at different situations. To improve accuracy of the resistance, the resistance may be calculated regularly (e.g., every day). After calculation, the resistance of the battery 10 is pre-stored into the storage system 140 of the electronic device 1.

The calculation module 120 calculates an open circuit voltage of the battery 10 according to the charging voltage, the charging current and the resistance if the battery is charging. The calculation module 120 calculates an open circuit voltage of the battery 10 according to the discharging voltage, the discharging current and the resistance if the battery is discharging. The open circuit voltage includes a charge open circuit voltage or a discharge open circuit voltage.

In one embodiment, the charge open circuit voltage is calculated according to the charging voltage and the charging current of the battery 10. A formula for calculating the charge open circuit voltage is as follows: Vc=V1−I1*R, wherein Vc represents the charge open circuit voltage, V1 represents the charging voltage, I1 represents the charging current, and R represents the resistance. Additionally, the charging voltage Va and V1 are read at different times. In one embodiment, the charging voltage Va is read before the charging voltage V1.

The discharge open circuit voltage is calculated according to the discharging voltage and the discharging current of the battery 10. A formula for calculating the discharge open circuit voltage is as follows: Vd=V2+I2*R, wherein Vd represents the discharge open circuit voltage, V2 represents the discharging voltage, I2 represents the discharging current, and R represents the resistance. Additionally, the charging voltage Vb and V2 are read at different times. In one embodiment, the charging voltage Vb is read before the charging voltage V2.

The search module 130 searches for the battery percentage corresponding to the open circuit voltage. In one embodiment, the search module 130 searches for the battery percentage in the table as shown in FIG. 4 according to the open circuit voltage.

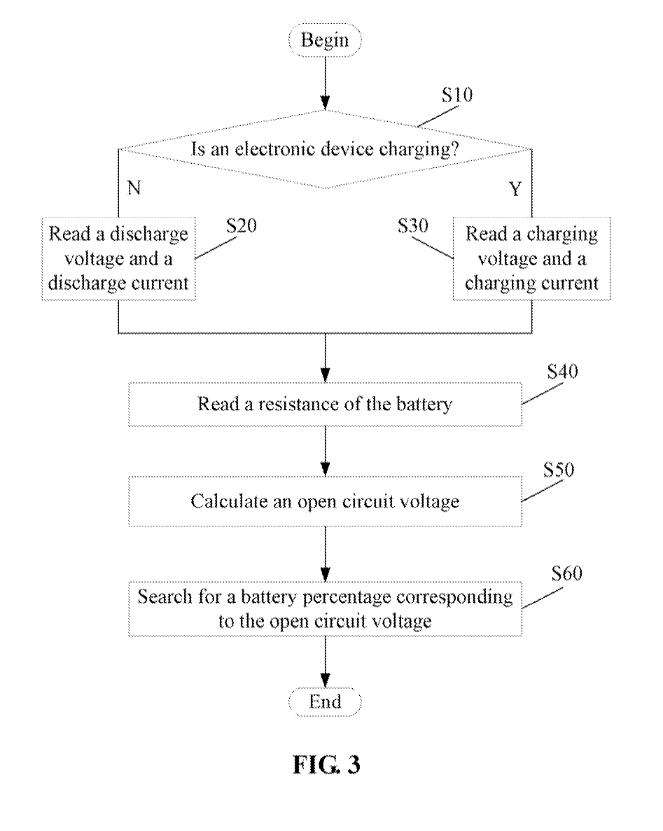

FIG. 3 is a flowchart of one embodiment of an open circuit voltage calculating method. Depending on the embodiment, additional steps may be added, others deleted, and the ordering of the steps may be changed.

In step S10, the determination module 100 determines if the battery 10 of the electronic device 1 is charging. In one embodiment, if a current is flowing from the charger 2, the determination module 110 determines that battery 10 of the electronic device 1 is charging, the procedure goes to step S20. If the current is not flowing from the charger 2, the determination module 110 determines that battery 10 of the electronic device 1 is discharging, the procedure goes to step S30.

In step S20, the reading module 110 reads a charging voltage and a charging current of the battery 10. In one embodiment, the reading module 110 reads the charging voltage and the charging current of the battery 10 from the charging current circuit. The charging current circuit is generated by the battery 10 when the battery 10 is charging.

In step S30, the reading module 110 also reads a discharging voltage and a discharging current of the battery 10. In one embodiment, the reading module 110 reads the discharging voltage and the discharging current of the battery 10 from the discharging current circuit. The discharging current circuit is generated by the battery 10 when the battery 10 is discharging.

In step S40, the reading module 110 reads a resistance of the battery 10. The resistance of the battery 10 is pre-stored into the storage system 140 of the electronic device 1. The resistance is calculated by a formula R as mentioned above By influence of temperature of the battery 10 or other factors (e.g., charging times of the battery 10), the resistance may vary at different situations. For improving accuracy of the resistance, the resistance may be calculated in an interval (e.g., every day).

In step S50, the calculation module 120 calculates an open circuit voltage of the battery 10. In one embodiment, if the battery 10 is charging, the open circuit voltage is calculated by a formula of Vc as mentioned above. If the battery 10 is discharging, the open circuit voltage is calculated by the formula of Vd as mentioned above.

In step S60, the search module 130 searches for the battery percentage corresponding to the open circuit voltage. For example, if the open circuit voltage is 4.2V, the search module 130 searches for the battery percentage 100% in the table as shown in FIG. 4. The search module 130 further displays the searched the battery percentage in the screen 160.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. An electronic device, the electronic device comprising:
a battery;
at least one processor; and
a storage system, and one or more programs that are executed by the at least one processor to perform an open circuit voltage calculating method, the method comprising:
reading a charging voltage and a charging current of the battery, in response to a determination that the battery is charging;
reading a discharging voltage and a discharging current of the battery, in response to the determination that the battery is discharging;
reading a resistance of the battery stored in the storage system calculating an open circuit voltage of the battery according to the charging voltage, the charging current and the resistance when the battery is charging;
calculating the open circuit voltage of the battery according to the discharging voltage, the discharging current and the resistance when the battery is discharging; and
searching for a battery percentage corresponding to the open circuit voltage in a table, wherein the table is stored in the storage system and indicates a relation between the battery open circuit voltage and the battery percentage.

2. The electronic device of claim 1, wherein a charging current circuit is generated by the battery when the battery is charging, and the charging voltage and the charging current of the battery are read from the charging current circuit.

3. The electronic device of claim 1, wherein a discharging current circuit is generated by the battery when the battery is discharging, and the discharging voltage and the discharging current of the battery are read from the discharging current circuit.

4. The electronic device of claim 1, wherein the resistance is calculated according to a formula R=(Va−Vb)/(Ia−Ib), wherein Va represents the charging voltage, Ia represents the charging current, Vb represents discharging voltage, Ib represents the discharging current.

5. The electronic device of claim 1, wherein the open circuit voltage of the battery is calculated according to the charging voltage, the charging current and the resistance based on a formula Vc=V1−I1*R, wherein Vc represents the charge open circuit voltage, V1 represents the charging voltage, I1 represents the charging current, and R represents the resistance.

6. The electronic device of claim 1, wherein the open circuit voltage of the battery is calculated according to the discharging voltage, the discharging current and the resistance based on a formula Vd=V2−I2*R, wherein Vd represents the charge open circuit voltage, V2 represents the charging voltage, I2 represents the charging current, and R represents the resistance.

7. An open circuit voltage calculating method implemented by an electronic device comprising a battery, the method comprising:
reading a charging voltage and a charging current of the battery, in response to a determination that the battery is charging;
reading a discharging voltage and a discharging current of the battery, in response to the determination that the battery is discharging;
reading a resistance of the battery stored in a storage system of the electronic device;
calculating an open circuit voltage of the battery according to the charging voltage, the charging current and the resistance when the battery is charging;
calculating the open circuit voltage of the battery according to the discharging voltage, the discharging current and the resistance when the battery is discharging; and
searching for a battery percentage corresponding to the open circuit voltage in a table, wherein the table is stored in the storage system and indicates a relation between the battery open circuit voltage and the battery percentage.

8. The method of claim 7, wherein a charging current circuit is generated by the battery when the battery is charging, and the charging voltage and the charging current of the battery are read from the charging current circuit.

9. The method of claim 7, wherein a discharging current circuit is generated by the battery when the battery is discharging, and the discharging voltage and the discharging current of the battery are read from the discharging current circuit.

10. The method of claim 7, wherein the resistance is calculated according to a formula R=(Va−Vb)/(Ia−Ib), wherein Va represents the charging voltage, Ia represents the charging current, Vb represents discharging voltage, Ib represents the discharging current.

11. The method of claim 7, wherein the open circuit voltage of the battery is calculated according to the charging voltage, the charging current and the resistance based on a formula Vc=V1−I1*R, wherein Vc represents the charge open circuit voltage, V1 represents the charging voltage, I1 represents the charging current, and R represents the resistance.

12. The method of claim 7, wherein the open circuit voltage of the battery is calculated according to the discharging voltage, the discharging current and the resistance based on a formula Vd=V2−I2*R, wherein Vd represents the charge open circuit voltage, V2 represents the charging voltage, I2 represents the charging current, and R represents the resistance.

13. A non-transitory electronic device-readable medium having stored thereon instructions that, when executed by an electronic device, an electronic device comprising a battery, causing the electronic device to perform an open circuit voltage calculating method, the method comprising:
reading a charging voltage and a charging current of the battery, in response to a determination that the battery is charging;
reading a discharging voltage and a discharging current of the battery, in response to the determination that the battery is discharging;
reading a resistance of the battery stored in a storage system of the electronic device;
calculating an open circuit voltage of the battery according to the charging voltage, the charging current and the resistance when the battery is charging;
calculating the open circuit voltage of the battery according to the discharging voltage, the discharging current and the resistance when the battery is discharging; and
searching for a battery percentage corresponding to the open circuit voltage in a table, wherein the table is stored in the storage system and indicates a relation between the battery open circuit voltage and the battery percentage.

14. The non-transitory electronic device-readable medium of claim 13, wherein a charging current circuit is generated by the battery when the battery is charging, and the charging voltage and the charging current of the battery are read from the charging current circuit.

15. The non-transitory electronic device-readable medium of claim 13, wherein a discharging current circuit is generated by the battery when the battery is discharging, and the discharging voltage and the discharging current of the battery are read from the discharging current circuit.

16. The non-transitory electronic device-readable medium of claim 13, wherein the resistance is calculated according to a formula R=(Va−Vb)/(Ia−Ib), wherein Va represents the charging voltage, Ia represents the charging current, Vb represents discharging voltage, Ib represents the discharging current.

17. The non-transitory electronic device-readable medium of claim 13, wherein the open circuit voltage of the battery is calculated according to the charging voltage, the charging current and the resistance based on a formula Vc=V1−I1*R, wherein Vc represents the charge open circuit voltage, V1 represents the charging voltage, I1 represents the charging current, and R represents the resistance.

18. The non-transitory electronic device-readable medium of claim 13, wherein the open circuit voltage of the battery is calculated according to the discharging voltage, the discharging current and the resistance based on a formula Vd=V2−I2*R, wherein Vd represents the charge open circuit voltage, V2 represents the charging voltage, I2 represents the charging current, and R represents the resistance.
